(19) United States
(12) Patent Application Publication
(10) Pub. No.: US 2015/0154469 A1
(43) Pub. Date: Jun. 4, 2015

(54) PATTERN RECOGNITION METHOD AND APPARATUS FOR THE SAME

(71) Applicant: Postech Academy-Industry Foundation, Gyeongsangbuk-do (KR)

(72) Inventors: Sang Su Park, Gwangju (KR); Hyun Sang Hwang, Daegu (KR); Byoung Hun Lee, Gwangju (KR); Byung Geun Lee, Gwangju (KR); Bo Reom Lee, Seoul (KR); Moon Gu Jeon, Gwangju (KR)

(21) Appl. No.: 14/556,716

(22) Filed: Dec. 1, 2014

(30) Foreign Application Priority Data
Dec. 4, 2013 (KR) 10-2013-0149989
Dec. 4, 2013 (KR) 10-2013-01499988

(51) Int. Cl. G06K 9/62; G06N 3/08; G11C 13/00

(52) U.S. Cl. CPC G06K 9/62; G11C 13/0002; G06N 3/08

(57) ABSTRACT

The present invention relates to a pattern recognition method and a pattern recognition apparatus for the same. According to the present invention, a pattern recognition method comprises: receiving data of a recognition object having a pattern; and recognizing the pattern using an electronic device having a synapse characteristic including a plurality of RRAMs (Resistance Random Access Memories), wherein each RRAM includes a variable resistance layer and has multiple memory states depending on variations in resistance of the variable resistance layer.

Priority to Korean patent application number 10-2013-0149988 filed on Dec. 4, 2013 and 10-2013-0149989 filed on Dec. 4, 2013, the entire disclosure of which is incorporated by reference herein, is claimed.

### BACKGROUND OF THE INVENTION

1. Field of the invention

The present invention relates to a pattern recognition method and a pattern recognition apparatus for the same.

2. Related Art

Information society demands a technology that may efficiently process more information using less energy.

However, an increase in the amount of information to be processed per unit semiconductor chip is predicted to put obstacles in the way of a further growth of the conventional semiconductor-based IT technologies.

Although various subjects of research from innovative material to ultra low-power system are being suggested under the title of sustainable IT technology, they are still far away from being specifically established.

Meanwhile, a basic source technology, neuromorphic, has been proposed that may be applied to future semiconductor techniques. This technology is expected to be able to process information with very low energy. More and more attention is being drawn to, among others, a technique of implementing synapse or neurons, as core elements of the neuromorphic technology, in the form of solid electronic devices and using the pre-established integration techniques to realize high-level learning functions and power saving functions.

In case a neuromorphic-applied cross-point array structure consists only of memory devices, a reading error may occur due to current leakage in its nearby area. To address this issue, a selecting device, e.g., diode, which plays a role as a switch is needed.

Formation of a selecting device requires a process of sequentially stacking switching devices and resistive switching memories. If two films of different properties are deposited at high temperature, an undesired change in characteristics occurs at the interface between the films. Particularly, defects tend to concentrate on the interface, and this renders it difficult to obtain theoretical current-voltage characteristics.

The CMOS neuron and the RRAM synapse device need to meet their respective operational conditions for simultaneous mutual operations. A too low current level of the RRAM synapse might not be recognized by the CMOS neuron. The CMOS neuron cannot withstand a too high current level of the synapse device. Sequential application of pulses from the RRAM synapse device for potentation and depression should not be subjected to a sharp variation.

The proposed RRAM-based electronic device, despite the advantage of no need of selecting devices, suffers from requiring a high operation voltage and a rapid variation in current value upon depression.

An electronic device to be implemented as useful one should not undergo an abrupt change in resistance over voltage variation for SET and RESET operations. The filament types cause abrupt sets and abrupt resets, and in such case, gradual variation in resistance may be rarely expected. Without the resistance gradually varied, the synapse device would exhibit little plasticity.

Meanwhile, research is underway for automatically recognizing sound (voice) or image patterns but does not go beyond mere image restoration.

### PRIOR ART DOCUMENTS

### Patent Documents

Korean Patent Application Publication No. 10-2010-0129741 (published on Dec. 9, 2010)

### SUMMARY OF THE INVENTION

An object of the present invention is to provide a pattern recognition method and apparatus with increased recognition efficiency.

The objects of the present invention is achieved by a pattern recognition method, comprising: receiving data of a recognition object having a pattern; and recognizing the pattern using an electronic device of a synapse characteristic including a plurality of RRAMs (Resistance Random Access Memories), each RRAM includes a variable resistance layer and has multiple memory states depending on variations in resistance of the variable resistance layer.

A resistance of the variable resistance layer may vary through the transfer of oxygen molecules a resistance of the variable resistance layer varies through the transfer of oxygen molecules. The variable resistance layer may include a polycrystalline (PrₓCa₁₋ₓ)MnO₃.

Each RRAM may include: a first metal layer; the variable resistance layer positioned on the first metal layer; a titanium nitride layer positioned on the variable resistance layer, the titanium nitride layer directly contacting the variable resistance layer; an internal resistance layer positioned on the titanium nitride layer; and a second metal layer positioned on the internal resistance layer.

The internal resistance layer may have a resistance between 1 kohm and 100 Mohm.

The internal resistance layer may include AlOₓ.

The recognition object may include at least one of a sound and an image.

The recognition object may include a voice signal, said recognizing comprises: analyzing a brainwave signal corresponding to the voice signal; extracting a cochlea signal; pre-processing the brainwave signal and the cochlea signal to be converted into a spiking neuron; and applying the spiking neuron to the electronic device, and the brainwave signal may include at least one of a first brainwave (perception) generated when a voice is heard and a second brainwave (imagination) generated when a voice is imagined.

The electronic device may include a plurality of layers including: an input layer to which the spiking neuron is applied, the input layer including a neuron; a first layer randomly connected with the input layer, the first layer including a smaller number of neurons than the input layer; a second layer connected with the first layer through a RRAM synapse; and an output neuron connected with the second layer.

The objects of the present invention may be achieved by a pattern recognition method using an electronic device having a synapse characteristics, the pattern recognition method comprising: converting a recognition object having a pattern into a per-coordinate signal; and recognizing the pattern from the per-coordinate signal using the electronic device, the electronic device includes a RRAM having a variable resistance layer.

The per-coordinate signal may include coordinate information and strength information.

A resistance of the variable resistance layer may vary through the transfer of oxygen molecules, and the per-coordinate strength may be recognized in an analog manner by the variation of the resistance.

The RRAM may include: a first metal layer; the variable resistance layer positioned on the first metal layer; a titanium nitride layer positioned on the variable resistance layer, the titanium nitride layer directly contacting the variable resistance layer; an internal resistance layer positioned on the titanium nitride layer; a second metal layer positioned on the internal resistance layer.

The variable resistance layer may include a polycrystalline (PrₓCa₁₋ₓ)MnO₃ layer, and the internal resistance layer may include AlOₓ.

The recognition object may include at least one of a sound and an image.

The recognition object may include a voice signal, and said recognizing comprises: analyzing a brainwave signal corresponding to the voice signal; extracting a cochlea signal; pre-processing the brainwave signal and the cochlea signal to be converted into a spiking neuron; and applying the spiking neuron to the electronic device, and the brainwave signal may include at least one of a first brainwave (perception) generated when a voice is heard and a second brainwave (imagination) generated when a voice is imagined.

The electronic device may include a plurality of layers including: an input layer to which the spiking neuron is applied, the input layer including a neuron; a first layer randomly connected with the input layer, the first layer including a smaller number of neurons than the input layer; a second layer connected with the first layer through a RRAM synapse; and an output neuron connected with the second layer.

The objects of the present invention may be achieved by a pattern recognition apparatus, comprising: an input unit receiving strength data of a recognition object having a pattern; and a recognizing unit recognizing the data input from the input unit using multiple memory states; and a determining unit determining the pattern from a result recognized by the recognizing unit.

The recognizing unit may include an electronic device having a synapse characteristic including a plurality of RRAMs, and each RRAM may include a variable resistance layer and has multiple memory states depending on variations in resistance of the variable resistance layer.

Each RRAM may include: a first metal layer; the variable resistance layer positioned on the first metal layer; a titanium nitride layer positioned on the variable resistance layer, the titanium nitride layer directly contacting the variable resistance layer; an internal resistance layer positioned on the titanium nitride layer; and a second metal layer positioned on the internal resistance layer.

According to the present invention, a pattern recognition method and apparatus with increased recognition efficiency are provided.

### BRIEF DESCRIPTION OF DRAWINGS

FIG. 1 is a concept view illustrating an electronic device according to the present invention;

FIG. 2 is a view illustrating a comparison between a human neural network and an electronic device according to the present invention;

FIG. 3A to FIG. 5B are views illustrating a method of manufacturing an electronic device according to the present invention;

FIG. 6 is a view illustrating an electronic device manufactured according to the present invention;

FIG. 7 is a view illustrating electrical characteristics of a conventional electronic device without a variable resistance layer;

FIG. 8 is a view illustrating electrical characteristics obtained when a resistor is connected with a conventional electronic device without a variable resistance layer;

FIG. 9 is a view illustrating electrical characteristics of an electronic device manufactured according to the present invention.

FIG. 10 is a view illustrating analog characteristics of an electronic device manufactured according to the present invention;

FIG. 11 is a view illustrating current characteristics as per pulse count of a conventional electronic device without a variable resistance layer;

FIG. 12 is a view illustrating current characteristics as per pulse count of an electronic device according to the present invention;

FIGS. 13 and 14 are views illustrating experimental results of testing durability of an electronic device produced according to the present invention;

FIG. 15 is a view illustrating experimental results of testing reliability of an electronic device produced according to the present invention;

FIG. 16 is a view illustrating neuromorphic speech processing;

FIG. 17 illustrates an experiment for measuring a brainwave reaction;

FIG. 18 is a flowchart illustrating neuromorphic speech system according to an experimental example;

FIG. 19 is a view illustrating classifications of brainwave reactions obtained by an experiment on a speech sound;

FIG. 20 is a view illustrating time and frequency domain results for a, i, and u;

FIG. 21 is a view illustrating a pretreatment on a brainwave signal and a coachlea signal;

FIG. 22 is a view illustrating a neural network simulated for processing; and

FIG. 23 is a view illustrating results of a recognition test in an experimental example according to the present invention.

### DETAILED DESCRIPTION OF EMBODIMENTS

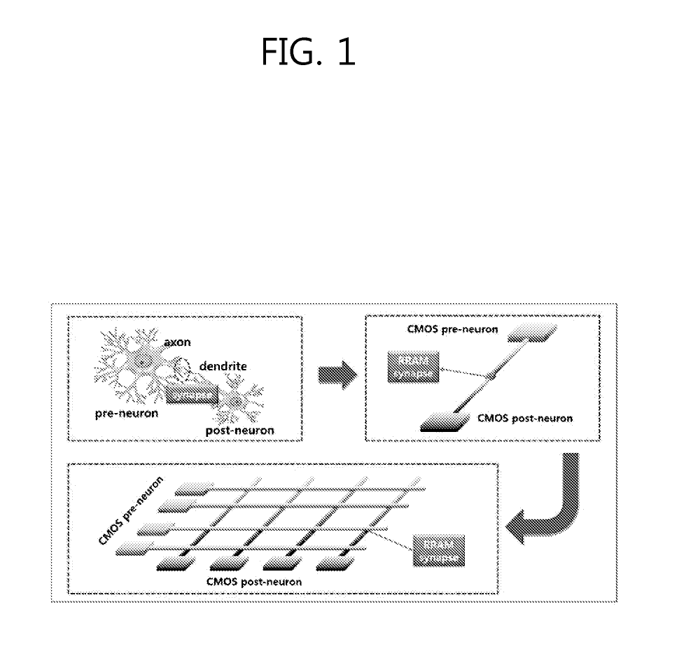

FIG. 1 is a concept view illustrating an electronic device according to the present invention. A human brain includes a pre-neuron providing information, a post-neuron receiving information, and a synapse connecting the pre-neuron with the post-neuron. According to the present invention, an electronic device has neuromorphic characteristics constituted of neurons and synapses, and the pre-neuron and post-neuron may be implemented of CMOSs, and the synapse is implemented of a RRAM.

The RRAM is a resistive memory and its resistance varies according to voltages applied thereto.

According to the present invention, the RRAM implements the characteristics of synapse in a simple manner and does not require a selecting device such as transistor or diode. No need of a selecting device comes from the fact that the RRAM has self-rectifying characteristics. According to the present invention, the RRAM may include an internal resistance layer, a titanium nitride (TiNx) layer, and a PCMO(Pr_{0.7}Ca_{0.3}MnO₃) layer that is a variable resistance layer. The PCMO layer may be in polycrystalline state. The variable resistance layer functions as a variable resistor through the transfer of oxygen molecules.

The internal resistance layer may be formed by various methods. From the beginning, an oxide film may be deposited under an oxygen-deficient condition, or after deposition of a metal (e.g., Al or Ti) easily oxidized, followed by formation of a capping metal, a thin oxide layer may be formed while a program/erase operation is performed.

The internal resistance layer plays a role as an internal resistor during a switching process to prevent an abrupt change in resistance from occuring during an SET process. Accordingly, a relatively smooth change in resistance may be secured. As the resistance of the internal resistance layer is too high, the voltage drop becomes severe, and as the resistance is too low, no effect is obtained. The internal resistance layer may have a resistance in a range from 1 kohm to 100 Mohm. The internal resistance layer may be formed of aluminum oxide or other various metal oxides such as TiOx, TaOx, and MoOx.

The RRAM according to the present invention may have a reduced number of abrupt sets or substantially no abrupt sets thanks to the variable resistance layer.

Hereinafter, the internal resistance layer is described as being formed of aluminum oxide, but the present invention is not limited thereto.

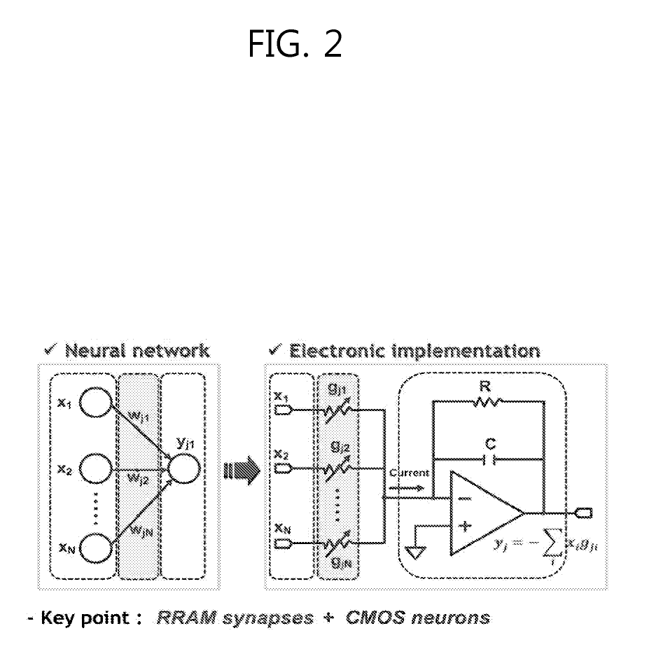

FIG. 2 is a view illustrating a comparison between a human neural network and an electronic device according to the present invention. The human neural network shown in the left-hand side of FIG. 2 simultaneously processes a plurality of inputs (x₁, x₂ . . . x_{N}) to produce a single output (yⱼ₁). In this process, the inputs and the output are connected with each other by way of synapses (wⱼ₁, wⱼ₂ . . . w_{jN}).

According to the present invention, the electronic device shown in the right-hand side of FIG. 2 simultaneously processes a plurality of inputs (x₁, x₂ . . . x_{N}) to produce a single output (yⱼ₁) as well. In this process, the inputs and the output are connected with each other by way of synapses (gⱼ₁, gⱼ₂ . . . g_{jN}).

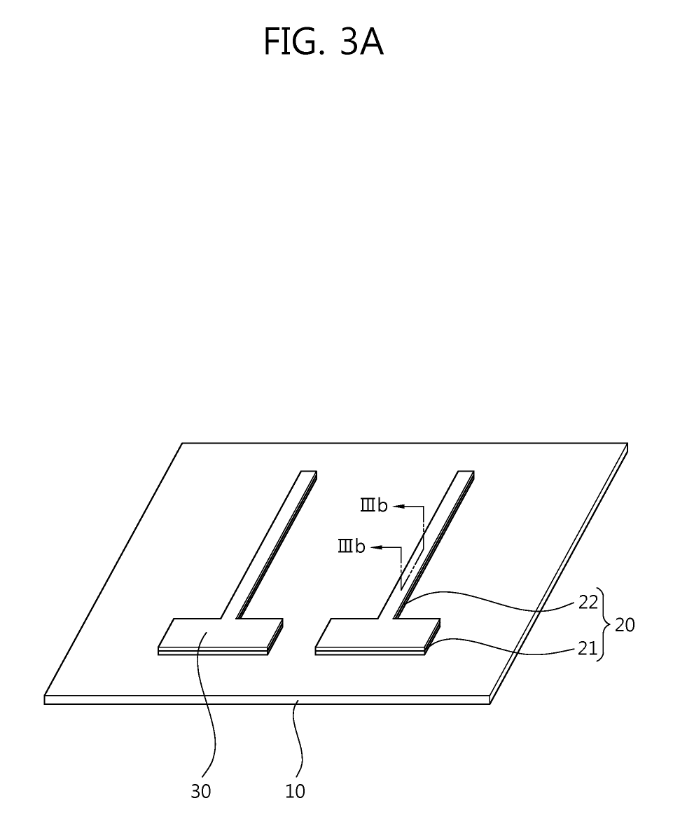

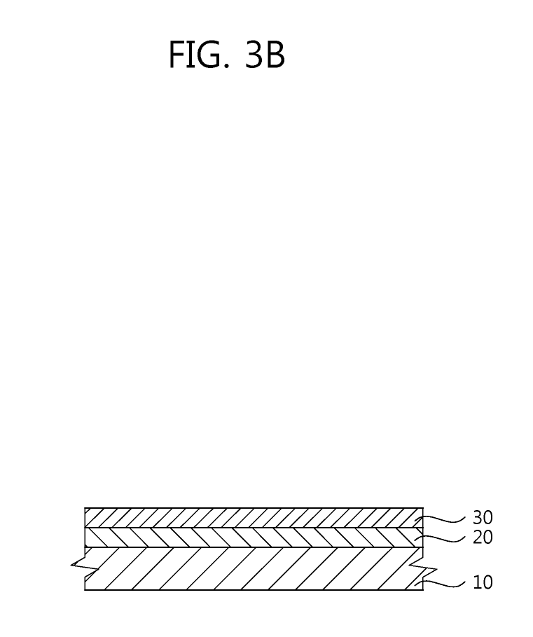

FIG. 3A to FIG. 5B are views illustrating a method of manufacturing an electronic device according to the present invention.

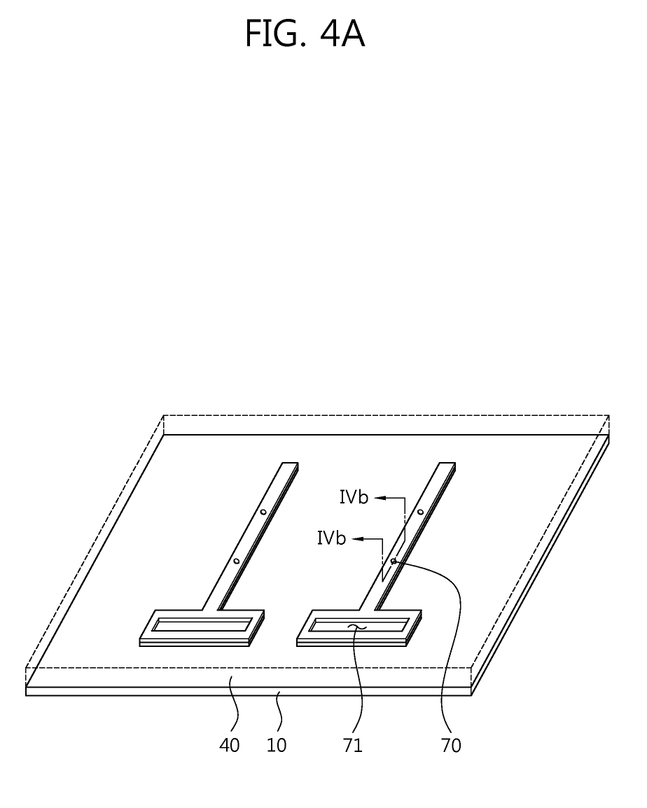

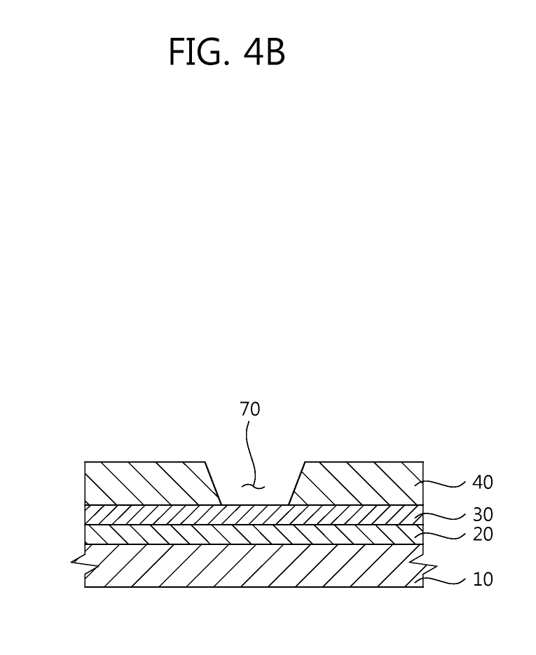

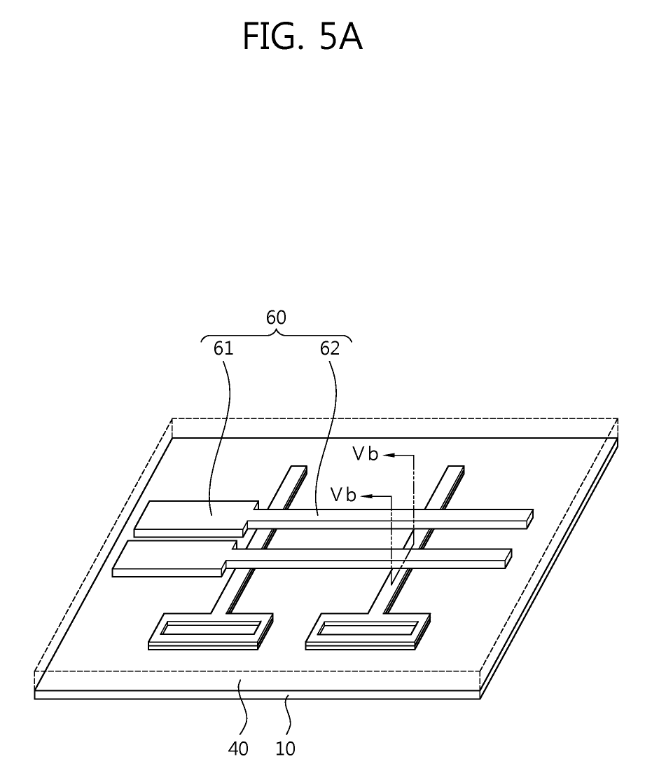

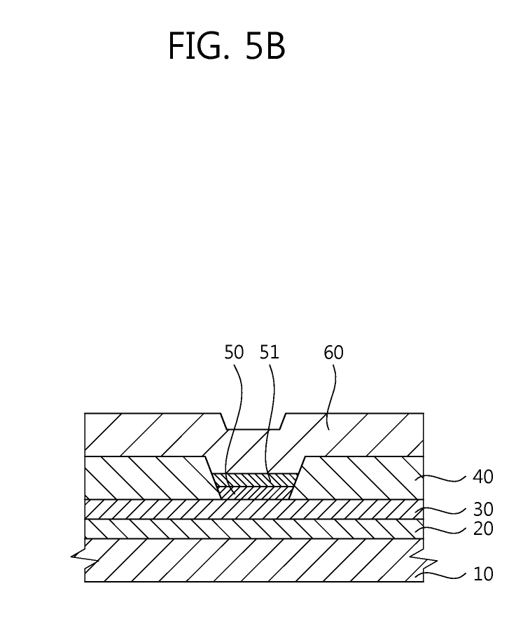

FIG. 3B are a cross-sectional view taken along line IIIb-IIIb. FIG. 4B is a cross-sectional view taken along line IVb-IVb. FIG. 5B is a cross-sectional view taken along line Vb-Vb.

First, a lower electrode layer (wire) 20 and a PCMO layer 30 are formed on a substrate 10 as shown in FIGS. 3A and 3B. The substrate 10 may be a silicon wafer.

The lower electrode layer 20 includes a pad 21 with a larger width and a line part 22 extended long from the pad 21. The lower electrode layer 20 is formed of platinum (Pt). In this case, since it is difficult to perform etching on platinum, a photosensitive layer is patterned, and a platinum layer is then formed. A pattern as shown in FIG. 3A may be formed through a lift-off process.

The PCMO layer 30 is prepared to be formed on the lower electrode layer 20 by depositing PCMO at 600° C. or more followed by photolithography. The PCMO layer 30 may be etched using reactive ion etching. The PCMO layer 30 is prepared in the polycrystalline form.

Then, an inter-layer insulating layer 40 is formed as shown in FIGS. 4A and 4B. The inter-layer insulating layer 40 may be a silicon nitride layer. Via holes 70 are formed through the inter-layer insulating layer 40 by a common photolithography method to expose the PCMO layer 30 on the line part 22 of the lower electrode layer 20. A via hole 71 is formed through the inter-layer insulating layer 40 up to the PCMO layer 30 on the pad 21 of the lower electrode layer 20, exposing the pad 21.

Next, as shown in FIGS. 5A and 5B, a titanium nitride layer 50, an aluminum oxide layer 51, and an upper electrode layer (wire) 60 are formed. The titanium nitride layer 50, the aluminum oxide layer 51, and the upper electrode layer 60 may also be formed by the process of forming and patterning a photosensitive layer, forming a metal layer, and performing a lift-off process, like the first fastening pin 20. The titanium nitride layer 50 may be formed by chemical vapor deposition (CVD) using a titanium precursor and nitrogen, and the titanium nitride layer 50 is formed on the PCMO layer 30 exposed by photolithography. The aluminum oxide layer 51 is formed through sputtering.

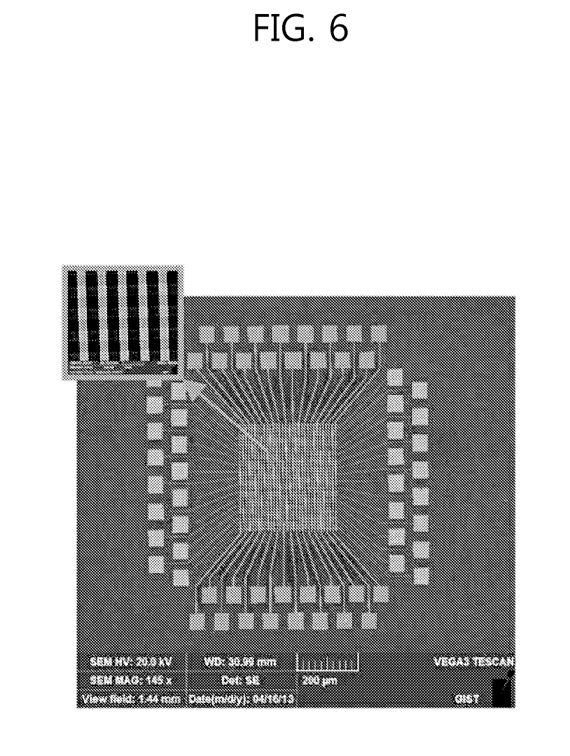

The upper electrode layer 60 is also referred to as a capping layer and may be formed of tungsten and/or platinum. The upper electrode layer 60 includes a pad 61 with a larger width and a line part 62 extended long from the pad 61. FIG. 6 illustrates an array electronic device produced through the above-described process.

In the electronic device produced thusly, the RRAM includes the polycrystalline PCMO, the titanium nitride layer, and the aluminum oxide layer, and the upper layer may be formed of Pt/PCMO/TiNx/Pt or Pt/PCMO/TiNx/W using a metal such as Pt or W.

The upper layer and the lower layer, independently from each other, may be formed of a single layer of Pt, W, TiN, Ag, Au, or Mo or a multi-layer thereof.

According to the present invention, switching may occur in the RRAM due to actions of PCMO and titanium nitride. Titanium nitride has a work function varying depending on the content of nitrogen. Accordingly, a switching action may be achieved by varying the work function and morphology of the PCMO abutting the titanium nitride. In particular, it is understood that switching occurs as oxygen molecules in the PCMO travel across the titanium nitride layer serving as oxygen storage by actions of nitride molecules in the titanium nitride.

According to the present invention, the RRAM is rendered to have multiple memory states depending on variations in resistance of the variable resistance layer. Specifically, if various memory states are created as the oxygen molecules in the variable resistance layer travel and thus the resistance varies, pattern recognition may be efficiently conducted.

The aluminum oxide operates as an internal resistor, thus reducing the abrupt sets or resets or making zero abrupt sets or resets.

Hereinafter, the present invention is described in greater detail through experimental results.

The thickness of the platinum layer, which is a lower electrode layer of the electronic device used in the experiment, was 80 nm PCMO was deposited at 600° C., reactive ion etching was used, and the thickness was 30 nm. The thickness of the silicon nitride layer used as the interlayer insulating film was 70 nm, and the PCMO layer prior to the formation of the titanium nitride layer was annealed for 30 minutes at 500° C., thus removing surface defects. The thickness of the titanium nitride layer was 20 nm, the thickness of the aluminum oxide layer was 10 nm, and the upper electrode layer was formed of Pt at the thickness of 70 nm. For comparison, the conventional electronic device used did not include an aluminum oxide layer.

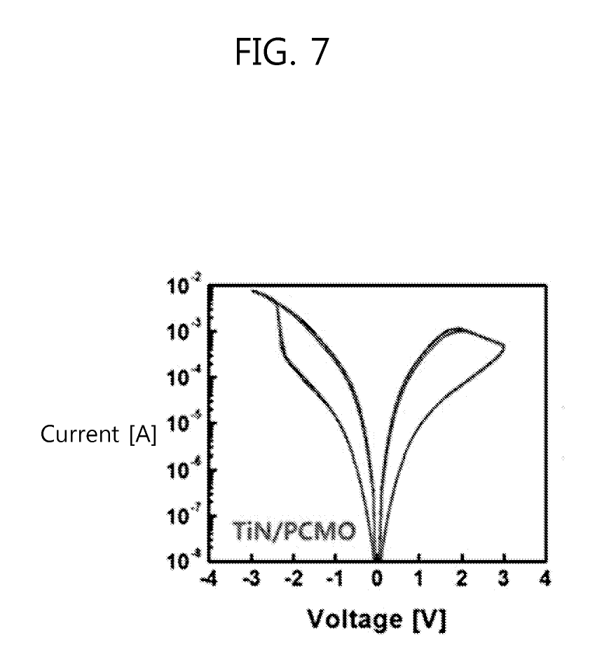

Referring to FIGS. 7 to 9, a reduction in abrupt sets due to introduction of an aluminum oxide layer is described.

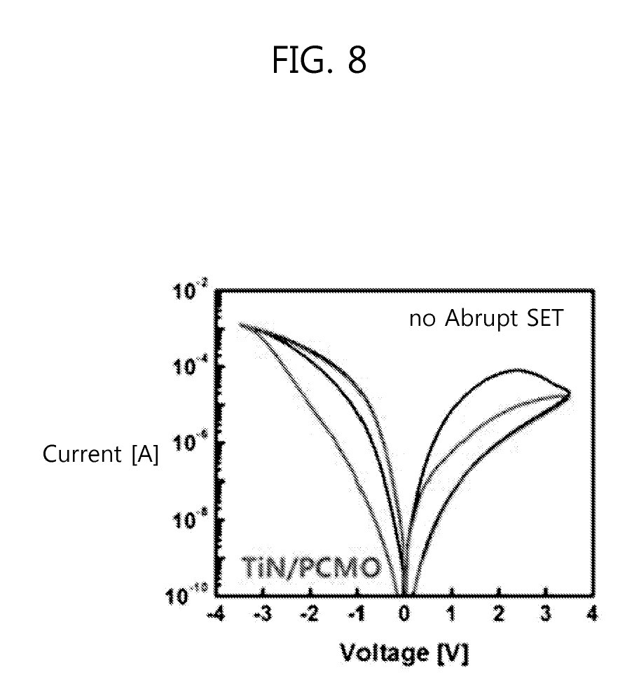

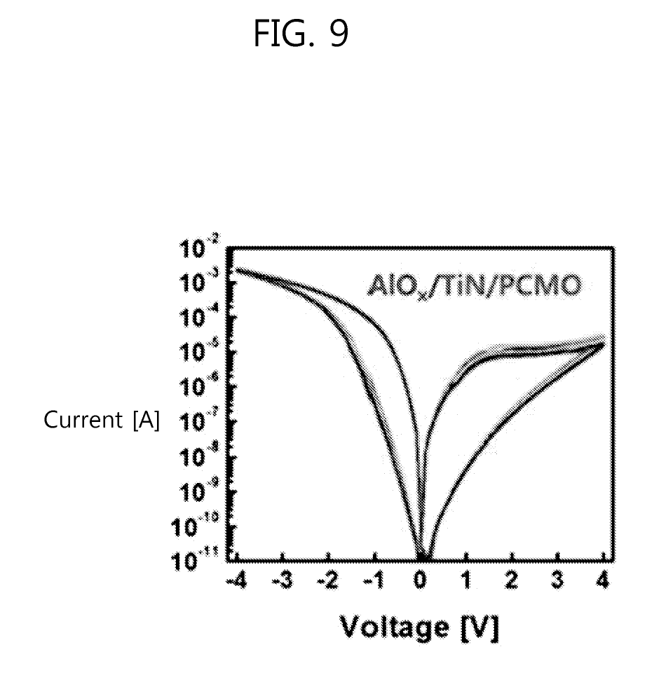

FIG. 7 shows electrical characteristics of a conventional electronic device with no variable resistance layer. FIG. 8 is a view illustrating electrical characteristics obtained when a resistor is connected with a conventional electronic device without a variable resistance layer. FIG. 9 is a view illustrating electrical characteristics of an electronic device according to the present invention.

It can be seen from FIG. 7 that the conventional electronic device has a high current level while remaining at a high on/off ratio. Accordingly, the operation voltage may be significantly reduced. However, an abrupt set may occur at a minus SET voltage.

As shown in FIG. 8, when a 1 Ω resistor is connected to the conventional electronic device, no abrupt set occurs at a minus SET voltage.

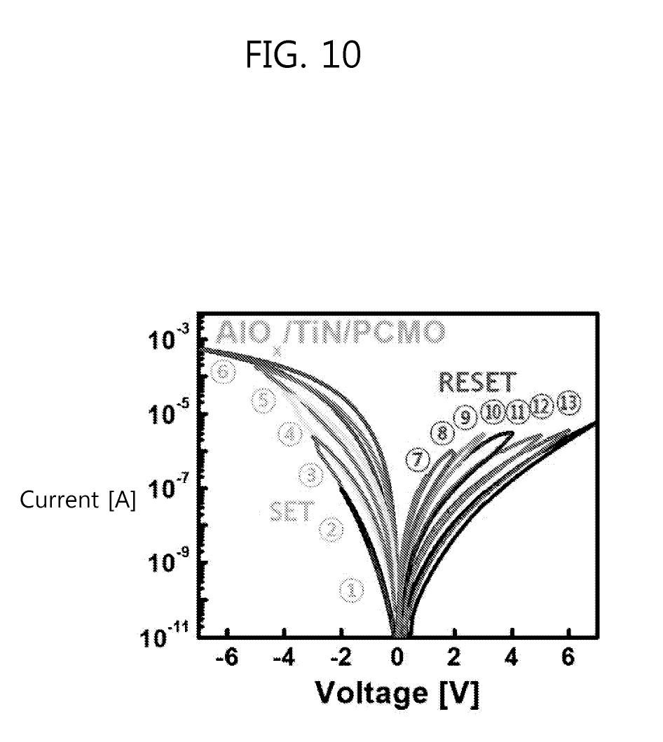

FIG. 9 is associated with an electronic device according to the present invention, and it can be seen from FIG. 10 that no abrupt set occurs at a minus SET voltage even without a separate resistor connection.

FIG. 10 is a view illustrating analog memory characteristics of an electronic device manufactured according to the present invention. Whenever leveled up and applied several times, a constant SET voltage showed analog memory characteristics. The RESET voltage also showed analog memory characteristics. When using a device produced in the atmosphere of 30 sccm nitrogen and gradually increasing the SET voltage, resistance changes of step 1 to step 6 were observed. The RESET voltage, when gradually increased, was also observed to show resistance changes of step 7 to step 13. It could be identified that each resistance state maintained memory characteristics while showing analog resistance changes of 13 steps. Or, no abrupt set was observed.

Nervous learning is achieved through synapse plasticity. To copy such synapse plasticity, securing the device's analog memory characteristics is a must. According to the analog memory characteristics, the resistance was steadily changed as per pulses applied, and such characteristic was secured through data actually measured.

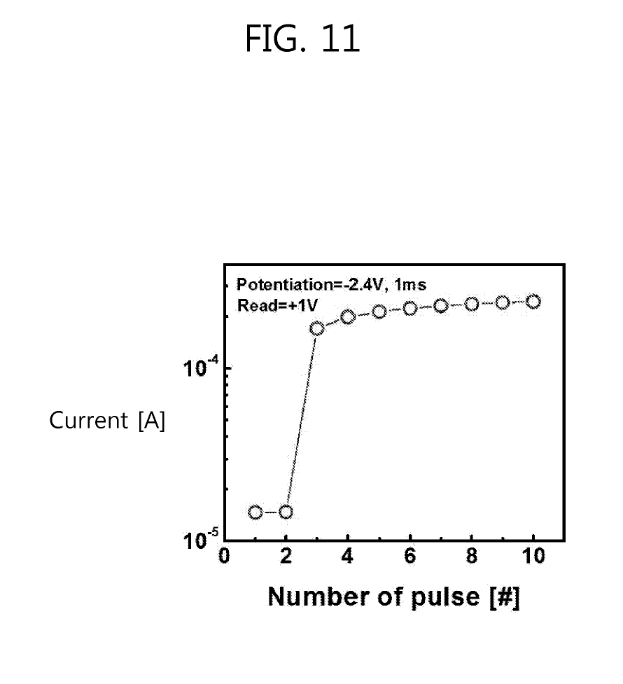

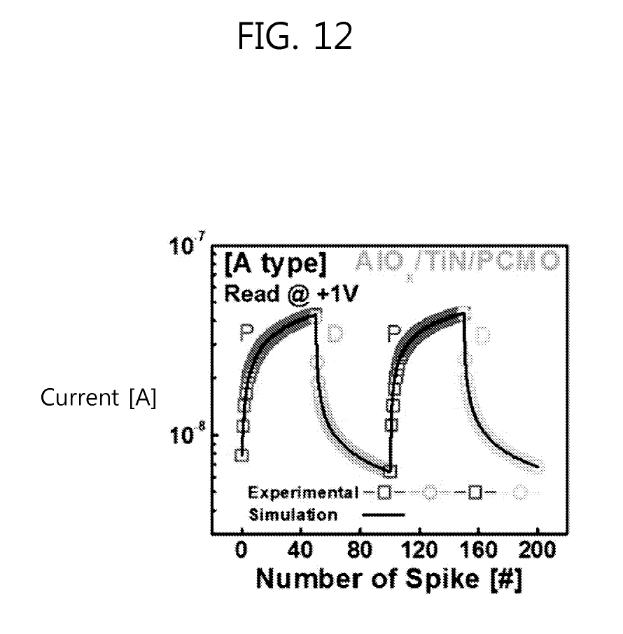

FIG. 11 is a view illustrating current characteristics as per pulse count of a conventional electronic device without a variable resistance layer. FIG. 12 is a view illustrating current characteristics as per pulse count of an electronic device according to the present invention.

The current characteristics as per pulse count represent the plasticity of device and are associated with learning ability. The plasticity is required to not show an abrupt change when pulses are sequentially applied for potentation and depression.

In the example shown in FIG. 11, when a spike whose pulse width is 1 ms was applied, an abrupt SEA occurred that causes a change in state within only a few times due to a high switching speed unlike in the conventional redox-type devices. It could be seen in FIG. 12 that abrupt changes were significantly reduced as compared with the example illustrated in FIG. 11. This is caused by the internal resistance layer, and thus means that the analog characteristic representing plasticity may be obtained by resistance changes.

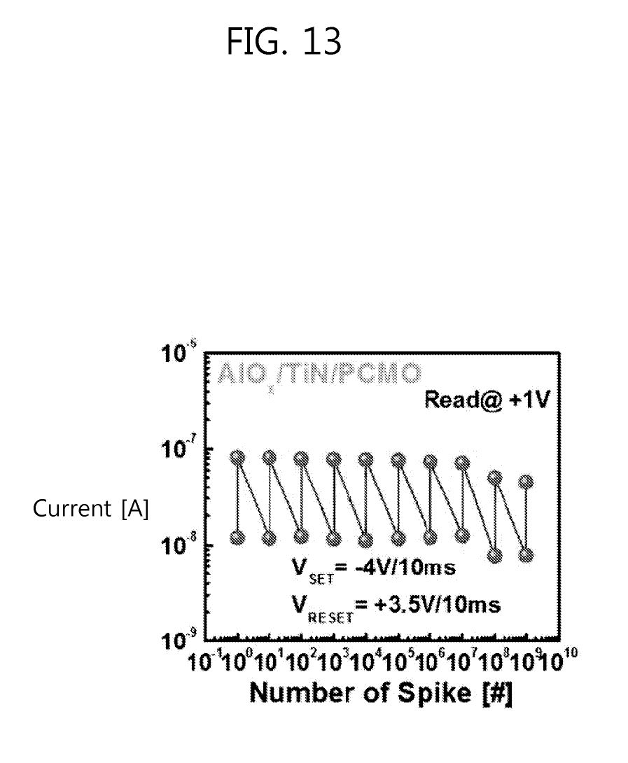

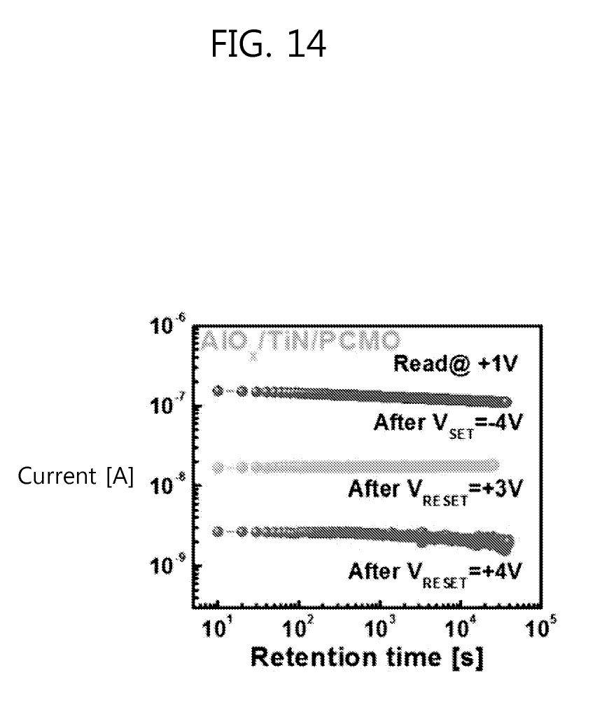

FIGS. 13 and 14 are views illustrating results of testing durability of an electronic device produced according to the present invention.

FIG. 13 illustrates the results obtained by reading the HRS and LRS of a resistor at the same voltage, with specific pulse voltage conditions applied. The SET voltage condition is −4 when a 10 ms pulse signal is applied, and the RESET voltage condition is +3.5V when a 10 ms pulse signal is applied. The read voltage is seen to stably operate even until switching is applied 10⁹ times at +1V.

FIG. 14 illustrates retention results in a multi-level state. Analog memories may be able to implement multi-level resistance states, but are useless unless each resistance state is maintained.

Retention was measured as per three resistance states in order to identify stable operation and memory characteristics of a device according to the present invention. Different voltage conditions (LRS=−4V, HRS1=+3V, and HRS2=+4V) were applied to the multi-level resistance states (LRS, HRS1, and HRS2), creating resistance states. Then, the resistance states were checked with a +1V read voltage applied. The current states were measured up to 3×10⁴ seconds while the +1V voltage was steadily applied, and each state showed zero-degradation memory characteristics.

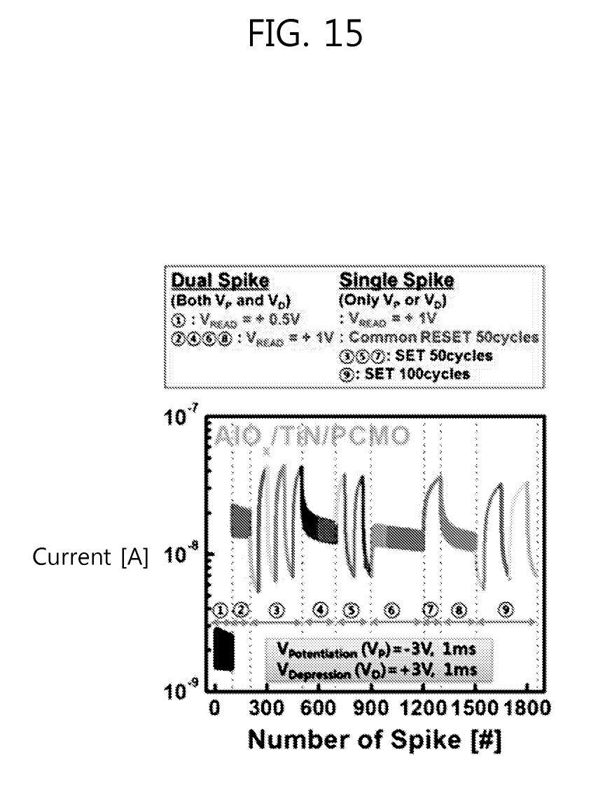

FIG. 15 is a view illustrating experimental results of testing, at varying operation conditions, reliability of an electronic device produced according to the present invention. The term “dual spike” represents when potentiation spikes and depression spikes are alternately applied, and the term “single spike” represents when only potentiation spikes or only depression skikes continue to be applied. The voltage pulse conditions were used as input spikes, and each potentiation spike, each depression spike, and each voltage used upon reading were used as V_{P}, V_{D}, and V_{READ}, respectively. The resultant graph shows that each step is denoted with a numeral. In the case of \textcircled{1}, upon dual spike operation, the current change was read at (+)0.5V, and in the cases of \textcircled{2}, \textcircled{4}, \textcircled{6}, and \textcircled{8}, current was read at (+1)1V.

In the single spike operation mode, the read voltage was fixed to (+1)1V, and comprisons were made accordng to spike cycles. The RESET mode was likewise fixed to 50 cycles. In the cases of \textcircled{3}, \textcircled{5}, and \textcircled{7}, only 50 cycles of SET spike were applied, and in the case of \textcircled{9}, 100 cycles were applied.

From the result shown in FIG. 15, it operated well without degradation also in various operation modes. Further, despite application of various spikes, the resistance state was varied gradually, not abruptly, thus offering reliability.

The above-described electronic device, i.e., an electronic device having synapse characteristics, may be used for pattern recognition. The pattern may be a sound (voice) or image, but not limited thereto. Each pattern has a per-coordinate signal (coordinate information and strength information), and the electronic device recognizes the pattern based on the per-coordinate signal.

Hereinafter, an example of voice recognition is described as an example of pattern recognition according to an embodiment of the present invention.

The above-described electronic device may be utilized for extracting an auditory center signal pattern and a cerebral nerve signal pattern reacting thereto, developing a simulator that may automatically recognize data coming from the brain, and/or developing a process for restoring a noisy auditory signal.

This means that auditory and EEG applications may be implemented. In other words, this increase the likelihood that a speech-impaired patient may communicate with others by generating voice signals.

The auditory steady state response (ASSR) of a brain to a voice signal is modulated by auditory selective attention (ASA) regarding a specific sound stream. A formant frequency is extracted from a brainwave generated from the patient as the human auditory cortex follows the envelope of a speech or constantly reacts to a variation in envelope, and a voice is then synthesized by a speech synthesizer, which is then fed back to the patient. By doing so, the patient may steadily generate brainwaves corresponding to the voices he intends to make.

Here, the brain signals include at least one of a first brainwave (perception) generated when a voice is heard and a second brainwave (imagination) generated when a voice is imagined.

A mathematical model is applied to the envelope of a brainwave signal measured from the auditory cortex, making it possible to reconfigure something close to a real voice signal (speech).

According to the present invention, a high-integrated RRAM synapse array and a CMOS neuron chip may be integrated with each other, enabling copying a human brain function and overcoming the technical limits put on the conventional Von Neumann-type digital circuits.

Further, a simple cross-point MIM structure of RRAM device is used to be able to implement the density of 10¹⁰/cm² close to that of the human brain's synapse. Further, the present technique may have various applications such as high-integrated memories or ultra low-power logic devices, and the pattern recognition technology of restoring complicated or impaired neural signals through learning may be applicable to security image processing, artificial eyes, or automatic navigation devices.

Hereinafter, neuromorphic speech processing using an electronic device according to the present invention is described using experimental examples.

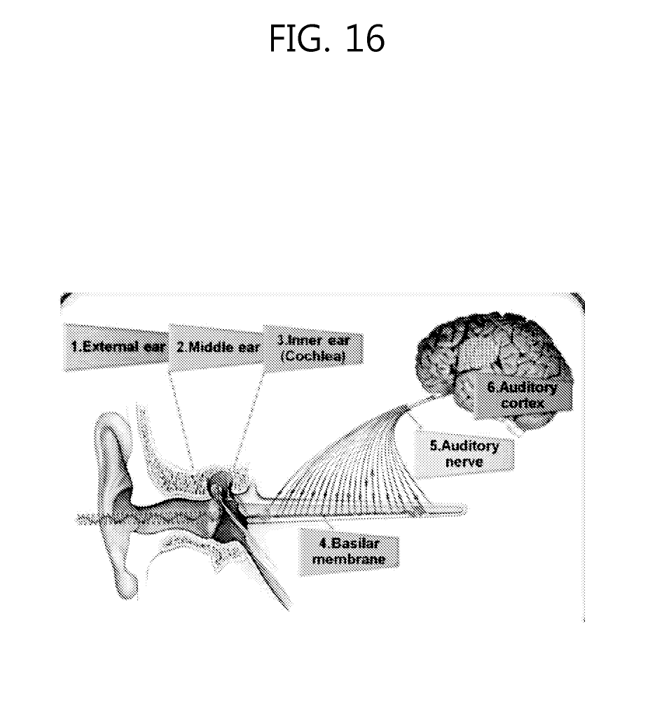

The neuromorphic speech processing is a new paradigm for understanding the brain process and is in recent research (refer to FIG. 16).

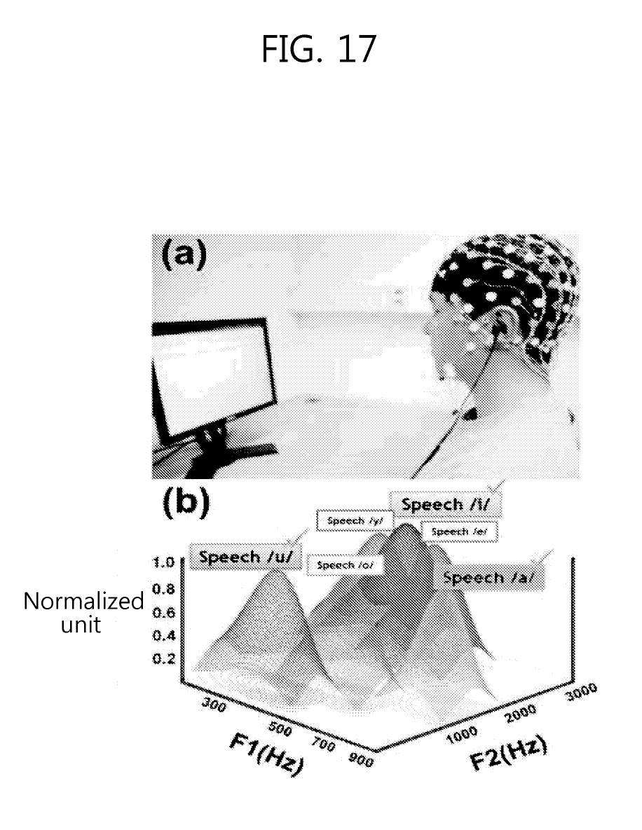

Among others, vowels are an important clue as to speech recognition. To extract a clear EEG reaction, selection of a stimulus is a critical factor. Given this, three Korean vowels, a/i/u, which differ a lot in formant frequency from each other, were picked up as stimuli (refer to FIG. 17). Random stimuli were suggested to avoid the subject's prejudice. FIG. 17A shows an example of brainwave experiment, and FIG. 17B shows formant frequencies of vowels.

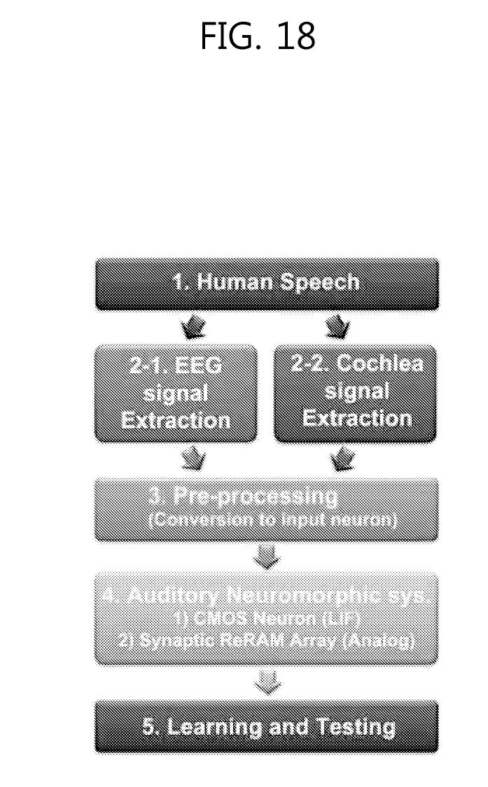

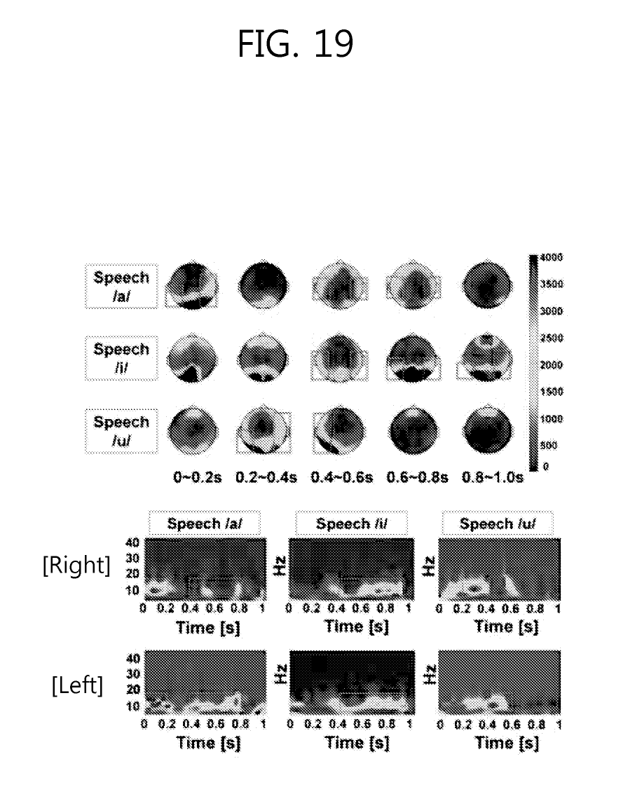

FIG. 18 is a flowchart illustrating neuromorphic speech system according to an experimental example. The flowchart is described with reference to FIGS. 19 to 23.

FIG. 19 is a view illustrating classifications of EEG reactions obtained by an experiment on a speech sound. EEG signals were obtained through eight electrodes attached onto left and right temples. As shown in FIG. 19, a majority of alpha band (8-13 Hz) power shows statistically different figures under three conditions at the left and right temple areas. Further, a clear reaction to three phonemes was observed at the temple areas of the topography. As a brain reaction to “a,” high activation was shown at the left and right temple areas between 0 seconds and 0.2 seconds and between 0.4 seconds and 0.8 seconds. As a brain reaction to “i,” high activation was shown at the left and right temple areas between 0.4 seconds and 0.9 seconds, and as a brain reaction to “u,” high activation was shown within 0.2 seconds and 0.4 seconds at the right temple area and between 0.4 seconds and 0.6 seconds at the left temple area (red boxed portion).

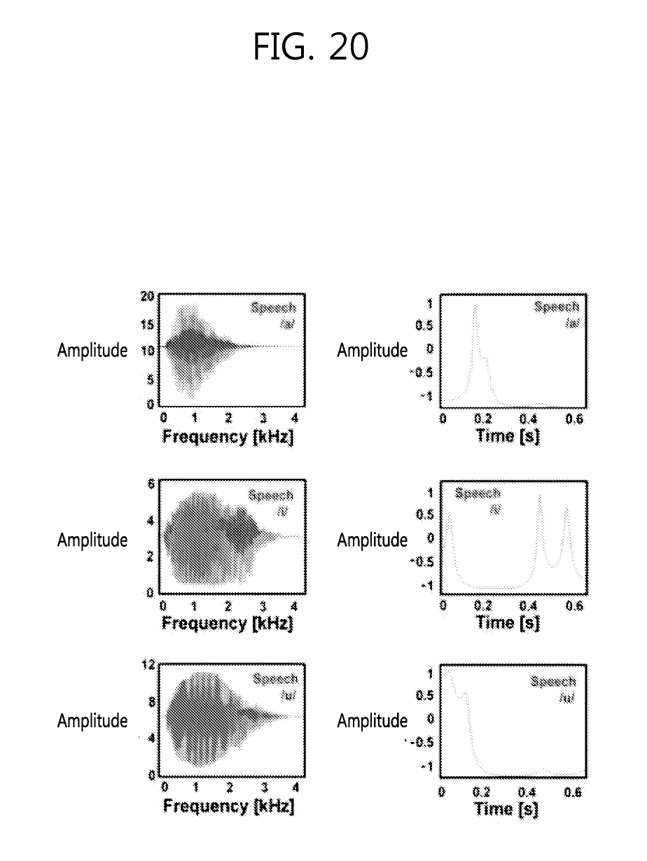

FIG. 20 is a view illustrating time and frequency domain results for a, i, and u.

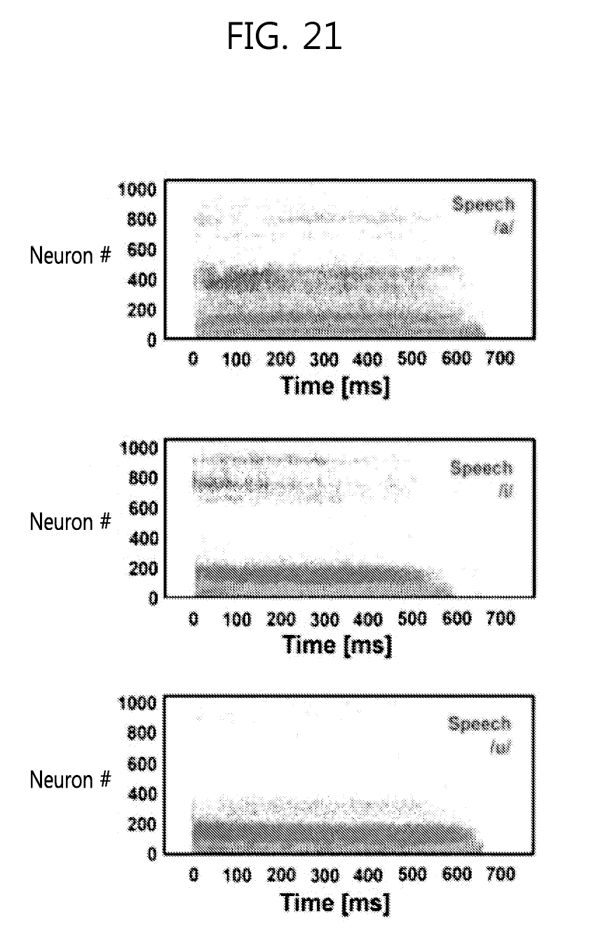

Thereafter, as shown in FIG. 21, the signal extracted from the EEG and cochlea was pre-processed to be converted to an input neuron using an emulator. A leaky integrate and fire (LIF) model was used in the simulation.

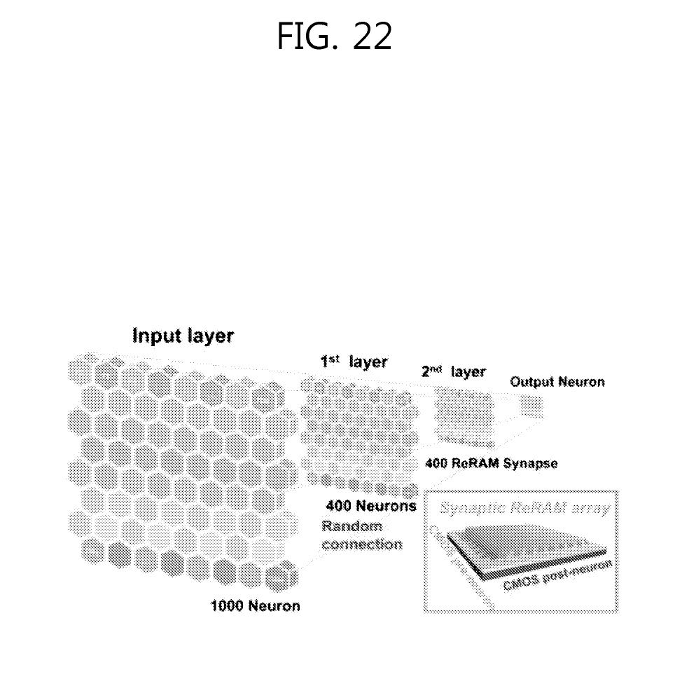

As shown in FIG. 22, the firing spikes of 1,000 input excitatory neurons on the cochlea layer were randomly connected to the first layer (400 neurons). The connections were randomly selected as 40% inhibitory, and the remainder was excitatory. Thereafter, the processed data is directly provided to a second layer of the feed-forward spiking neural network having 400ReRAM synapse. The network is determined in a winner-take-all manner.

The electronic device produced according to the present invention applies to, among others, the second layer. The input layer and the first layer, as devices consisting of CMOS neurons, each may have a configuration as shown in FIG. 2.

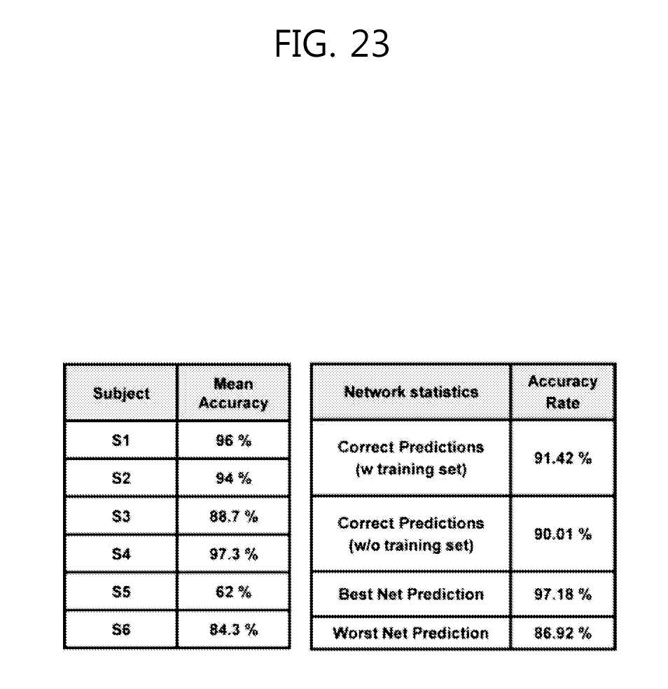

The experimental result shows a high performance of a 90% or more prediction rate, as shown in FIG. 23.

A pattern recognition apparatus according to the present invention is described with reference to FIG. 22. The pattern recognition apparatus according to the present invention includes an input unit receiving strength data of a recognition object having a pattern, a recognizing unit recognizing the data input from the input unit using multiple memory states, and a determining unit determining a pattern from a result recognized by the recognizing unit. Here, a RRAM according to the present invention is included in the recognizing unit. The RRAM includes a variable resistance layer. Multiple memory states are provided depending on variations in resistance of the variable resistance layer.

RRAM-containing synapse layers are positioned between the input layer and the first layer, between the first layer and the second layer, and between the second layer and the output unit (output neuron) as shown in FIG. 22.

What is claimed is:

1. A pattern recognition method, comprising:
receiving data of a recognition object having a pattern; and
recognizing the pattern using an electronic device of a synapse characteristic including a plurality of RRAMs (Resistance Random Access Memories), wherein each RRAM includes a variable resistance layer and has multiple memory states depending on variations in resistance of the variable resistance layer.

2. The pattern recognition method of claim 1, wherein a resistance of the variable resistance layer varies through the transfer of oxygen ion molecules.

3. The pattern recognition method of claim 2, wherein the variable resistance layer includes a polycrystalline (PrₓCa₁₋ₓ)MnO₃.

4. The pattern recognition method of claim 3, wherein each RRAM includes:
a first metal layer;
the variable resistance layer positioned on the first metal layer;
a titanium nitride layer positioned on the variable resistance layer, the titanium nitride layer directly contacting the variable resistance layer;
an internal resistance layer positioned on the titanium nitride layer; and
a second metal layer positioned on the internal resistance layer.

5. The pattern recognition method of claim 4, wherein the internal resistance layer has a resistance between 1 kohm and 100 Mohm

6. The pattern recognition method of claim 5, wherein the internal resistance layer includes AlOₓ.

7. The pattern recognition method of claim 1, wherein the recognition object includes at least one of a sound and an image.

8. The pattern recognition method of claim 7, wherein the recognition object includes a voice signal, wherein said recognizing comprises:
analyzing a brainwave signal corresponding to the voice signal;
extracting a cochlea signal;
pre-processing the brainwave signal and the cochlea signal to be converted into a spiking neuron; and
applying the spiking neuron to the electronic device, and wherein the brainwave signal includes at least one of a first brainwave (perception) generated when a voice is heard and a second brainwave (imagination) generated when a voice is imagined.

9. The pattern recognition method of claim 8, wherein the electronic device includes a plurality of layers including:
an input layer to which the spiking neuron is applied, the input layer including a neuron;
a first layer randomly connected with the input layer, the first layer including a smaller number of neurons than the input layer;
a second layer connected with the first layer through a RRAM synapse; and
an output neuron connected with the second layer.

10. A pattern recognition method using an electronic device having a synapse characteristic, the pattern recognition method comprising:
converting a recognition object having a pattern into a per-coordinate signal; and
recognizing the pattern from the per-coordinate signal using the electronic device, wherein the electronic device includes a RRAM having a variable resistance layer.

11. The pattern recognition method of claim 10, wherein the per-coordinate signal includes coordinate information and strength information.

12. The pattern recognition method of claim 11, wherein a resistance of the variable resistance layer varies through the transfer of oxygen molecules, and wherein the per-coordinate strength is recognized in an analog manner by the variation of the resistance.

13. The pattern recognition method of claim 12, wherein the RRAM includes:
a first metal layer;
the variable resistance layer positioned on the first metal layer;
a titanium nitride layer positioned on the variable resistance layer, the titanium nitride layer directly contacting the variable resistance layer;
an internal resistance layer positioned on the titanium nitride layer; and
a second metal layer positioned on the internal resistance layer.

14. The pattern recognition method of claim 13, wherein the variable resistance layer includes a polycrystalline (PrₓCa₁₋ₓ)MnO₃ layer, and the internal resistance layer includes AlOₓ.

15. The pattern recognition method of claim 12, wherein the recognition object includes at least one of a sound and an image.

16. The pattern recognition method of claim 15, wherein the recognition object includes a voice signal, and wherein said recognizing comprises:
analyzing a brainwave signal corresponding to the voice signal; extracting a cochlea signal;
pre-processing the brainwave signal and the cochlea signal to be converted into a spiking neuron; and
applying the spiking neuron to the electronic device, and wherein the brainwave signal includes at least one of a first brainwave (perception) generated when a voice is heard and a second brainwave (imagination) generated when a voice is imagined.

17. The pattern recognition method of claim 16, wherein the electronic device includes a plurality of layers including:
an input layer to which the spiking neuron is applied, the input layer including a neuron;
a first layer randomly connected with the input layer, the first layer including a smaller number of neurons than the input layer;
a second layer connected with the first layer through a RRAM synapse; and
an output neuron connected with the second layer.

18. A pattern recognition apparatus, comprising:
an input unit receiving strength data of a recognition object having a pattern;
a recognizing unit recognizing the data input from the input unit using multiple memory states; and
a determining unit determining the pattern from a result recognized by the recognizing unit.

19. The pattern recognition apparatus of claim 18, wherein the recognizing unit includes an electronic device having a synapse characteristic including a plurality of RRAMs, and wherein each RRAM includes a variable resistance layer and has multiple memory states depending on variations in resistance of the variable resistance layer.

20. The pattern recognition apparatus of claim 19, wherein each RRAM includes:
a first metal layer;
the variable resistance layer positioned on the first metal layer;
a titanium nitride layer positioned on the variable resistance layer, the titanium nitride layer directly contacting the variable resistance layer;
an internal resistance layer positioned on the titanium nitride layer; and
a second metal layer positioned on the internal resistance layer.
